(19) United States
(12) Patent Application Publication
(10) Pub. No.: US 2026/0230088 A1
(43) Pub. Date: Aug. 6, 2026

(54) ELECTRONIC CONVERSION ARCHITECTURE COMPRISING A CONTINUOUS TIME SIGMA DELTA ANALOG TO DIGITAL CONVERTER AND A CALIBRATION METHOD THEREOF

(71) Applicant: STMicroelectronics International N.V., Geneva (CH)

(72) Inventors: Gaetano Cosentino, Catania (IT); Nicolo' Ivan Piazzese, Acireale (CT) (IT); Nino Gianfranco Bellantone, Catania (IT); Pasquale Giuseppe Imbesi, Catania (IT); Antonino Calcagno, Messina (IT)

(21) Appl. No.: 19/455,383

(22) Filed: Jan. 21, 2026

(30) Foreign Application Priority Data
Jan. 30, 2025 (IT) 102025000001626

(51) Int. Cl. H03M 3/00

(52) U.S. Cl. CPC H03M 3/38; H03M 3/462; H03M 3/464

(57) ABSTRACT

A conversion architecture comprising a Continuous Time Sigma Delta Analog to Digital Converter comprising a loop filter followed by an analog to digital converter and a feedback loop feeding back the output of the analog to digital converter through an internal digital to analog converter to obtain an error signal with respect to a input signal, which is fed to said loop filter, an output digital signal of the analog to digital converter being fed to a decimation chain of decimators, a local oscillator feeding a clock signal to said analog to digital converter, and, through a frequency divider, to said chain of decimators.

### CROSS REFERENCE TO RELATED APPLICATION(S)

This application claims priority of Italian patent application number 102025000001626, filed on 30 Jan. 2025, entitled “Electronic conversion architecture comprising a Continuous Time Sigma Delta Analog to Digital Converter and a calibration method thereof” which is hereby incorporated by reference to the maximum extent allowable by law.

### TECHNICAL FIELD

The description relates to an electronic conversion architecture comprising a Continuous Time Sigma Delta Analog to Digital Converter and a calibration method.

### BACKGROUND

Nowadays, the demands on the linearity of high-resolution D/A converters for measurement equipment and digital audio are so high that the achievable accuracy based upon matching of components in a standard process is not sufficient. Therefore, additional calibration techniques are used to achieve high resolution. A disadvantage of many calibration techniques is the need for a special calibration period. During this period, the converter cannot be used for conversion, which particularly limits the application range. Furthermore, a relatively large chip area is needed to store the error signals.

The DAC non-linearity is a key point in the design of DS A/D converters: in the Continuous Time Sigma Delta Analog to Digital Converters, such the SD ADC model SDA shown schematically in FIG. 1a, where DA and DD indicates the analog domain and digital domain of the signals, a DAC (circuit block S_{DAC}) is internal to a feedback loop. As shown, a loop filter LOF receives the input analog signal u and a feedback analog signal vd, its filtered output y being converted in an output digital signal v with the introduction of a quantization error eq in the ADC conversion circuit block S_{ADC}; the output digital signal v is fed back on the feedback loop comprising the DAC conversion, indicated by DAC circuit block S_{DAC}, in which the mismatch error eₘₘ is injected. The transfer function from the mismatch error eₘₘ to the digital output v is basically the same as the inherent signal transfer function. This filtering will not cancel the in-band mismatch noise. In the case of a SD DAC, SDD, which architecture is shown in FIG. 1b and correspond basically to that of FIG. 1A, with the DAC circuit block S_{D}AC placed at the output of the digital loop, the mismatch noise also remains unshaped.

For both cases in FIG. 1a, 1b, there are in-band spurious tones, or spurs, caused by the DAC mismatch noise; the distortion mechanism remains the same. DAC induced out-of-band tones are filtered out by the post-filtering (decimation filter or an analog filter), but the in-band DAC-mismatch related noise will not be attenuated. To cancel the mismatch noise in the presence of imprecise component matching, the DAC mismatch noise can be attenuated with digital error correction or spectrally shaped with dynamic element matching (DEM).

Dynamic matching of unit-DAC elements refers to scrambling the usage of DAC elements so that the signal-dependent deterministic mismatch noise is transformed into a wide-band noise. A basic feature in all dynamic element matching (DEM) methods is that they do not reduce the error, instead the error is moved from the signal band.

Unlike DEM methods, digital error correction (DEC) cancels the mismatch noise instead of shaping the spectrum. In the concept of digital error correction, the element selection remains static. The correction is based on measuring the mismatches by the so-called calibration setup. Foreground calibration is a linearization method introduced at the end of the 80's in the last century.

### SUMMARY

In one embodiment, a conversion architecture including a Continuous Time Sigma Delta Analog to Digital Converter including a loop filter, an analog to digital converter coupled to an output of the loop filter, and a feedback loop configured to feed back an output of the analog to digital converter through an internal digital to analog converter to obtain an error signal with respect to an input signal, the error signal being fed to the loop filter, a decimation chain of decimators configured to receive an output digital signal of the analog to digital converter, a local oscillator configured to feed a clock signal to the analog to digital converter, a frequency divider configured to receive the clock signal and provide a divided clock signal to the decimation chain of decimators, and circuitry configured to obtain a calibration tone based on a divided frequency outputted by the frequency divider to the decimation chain of decimators, inject the calibration tone in the feedback loop, obtain an estimation of power of a spurious tone based on a decimated signal taken from the decimation chain, generate a calibration signal as a function of the estimation of the power of the spurious tone, and send the calibration signal to the internal digital to analog converter, wherein the internal digital to analog converter includes an output adjustment arrangement configured to adjust an output analog signal of the internal digital to analog converter based on the calibration signal.

In one embodiment, a calibration method for a conversion architecture, the method including generating a calibration tone having an out-of-band frequency relative to a baseband signal of the conversion architecture, the conversion architecture including a Continuous Time Sigma Delta Analog to Digital Converter including a loop filter, an analog to digital converter, an internal digital to analog converter in a feedback loop, and a decimation chain of decimators, injecting the calibration tone in an input path of the analog to digital converter, obtaining a decimated signal from the decimation chain of decimators, estimating power of a spurious tone in the decimated signal, and adjusting output levels of the internal digital to analog converter with a calibration signal to reduce the estimated power.

In one embodiment, a Continuous Time Sigma Delta Analog to Digital Converter including a loop filter having an input and an output, an analog to digital converter coupled to the output of the loop filter and configured to generate an output digital signal, a decimation chain of decimators configured to receive the output digital signal and generate a decimated signal, a local oscillator configured to generate a clock signal for the analog to digital converter, a frequency divider configured to divide the clock signal and provide a divided clock signal to the decimation chain of decimators, an internal digital to analog converter configured to receive the output digital signal and generate a feedback analog signal, a first summation circuit block configured to sum the feedback analog signal and a calibration signal to generate a compensated feedback analog signal, a second summation circuit block configured to sum the compensated feedback analog signal and a calibration tone to generate a combined feedback signal, wherein the calibration tone is based on a divided frequency from the frequency divider, a difference circuit block configured to generate an error signal based on a difference between an input analog signal and the combined feedback signal, the error signal being coupled to the input of the loop filter, and a calibration circuit configured to measure power of a spurious tone in the decimated signal, the spurious tone being generated by mismatch in the internal digital to analog converter in response to the calibration tone, and generate the calibration signal to adjust the compensated feedback analog signal to reduce the power of the spurious tone.

### BRIEF DESCRIPTION OF THE DRAWINGS

One or more embodiments will now be described, by way of example only, with reference to the annexed figures, wherein:

FIG. 1a illustrates a Continuous Time Sigma Delta Analog to Digital Converters such as the SD ADC model SDA;

FIG. 1b illustrates a Continuous Time Sigma Delta Analog to Digital Converters such as the SD DAC, SDD, architecture;

FIG. 2 illustrates a continuous time Sigma Delta ADC (CTSD-ADC), comprising a non-ideal DAC with mismatches in its output levels, for instance due to differences in the component implementing the conversion;

FIG. 3 is a schematic circuit block diagram of a conversion architecture according to embodiments;

FIG. 4 is a schematic circuit block diagram of a conversion architecture according to embodiments showing further details;

FIG. 5 is a schematic circuit block diagram detailing a circuit of the architecture of FIG. 3;

FIG. 6 is a diagram of correction values applied by a calibration method of the conversion architecture according to embodiments;

FIGS. 7 and 8 are diagrams representing correction values applied by a calibration method of the conversion architecture according to embodiments in different iterations;

FIG. 9 is a circuit diagram of an embodiment of an analog to digital converter operating in the conversion architecture according to embodiments;

FIG. 10 is a circuit block diagram of a portion of the conversion architecture according to embodiments comprising the analog to digital converter of FIG. 9; and

FIG. 11 is circuit diagram of a portion of the conversion architecture according to embodiments comprising a further embodiment of analog to digital converter.

### DETAILED DESCRIPTION

The description relates to an electronic conversion architecture comprising a Continuous Time Sigma Delta Analog to Digital Converter comprising a loop filter followed by an analog to digital converter and a feedback loop feeding back the output of said analog to digital converter through an internal digital to analog converter to obtain an error signal with respect to a input signal, which is fed to said loop filter, an output digital signal of the analog to digital converter being fed to a decimation chain of decimators, a local oscillator feeding a clock signal) to said analog to digital converter, and, through a frequency divider, to said chain of decimators.

One or more embodiments may be applied e.g. to radio system, such as wide band (e.g. 25 MHz) and dual tuner band (34 MHz) radios.

One or more embodiments contribute in dealing with a number of issues which are recognized to exist in a context as discussed in the foregoing. One or more embodiments disclose a converter architecture having the features set forth in the claims that follow. One or more embodiments may relate to a corresponding method for calibrating a converter architecture.

As mentioned previously, various embodiments of the present disclosure regard a conversion architecture comprising a Continuous Time Sigma Delta Analog to Digital Converter comprising a loop filter followed by an analog to digital converter and a feedback loop feeding back the output of said analog to digital converter through an internal digital to analog converter to obtain an error signal (e) with respect to a input signal, which is fed to said loop filter, an output digital signal of the analog to digital converter being fed to a decimation chain of decimators, a local oscillator feeding a clock signal to said analog to digital converter, and, through a frequency divider, to said chain of decimators, wherein said conversion architecture further comprises: a circuit arrangement configured to obtain a calibration tone by a divided frequency outputted by said frequency divider to said chain of decimators and inject said calibration tone in said feedback loop, in particular in the input path of said analog to digital converter, a calibration arrangement which comprises: a spurious tone estimation circuit configured to obtain an estimation of the power of a spurious tone in said output signal based on a decimated signal taken in said decimation chain, and a calibration unit receiving said estimation of the power of a spurious tone and configured to send a calibration signal as function of said estimation of the power of a spurious tone to said digital to analog converter, which comprises an output adjustment arrangement configured to adjust an output signal of said internal digital to analog converter based on said a calibration signal.

In variant embodiments, said spur estimation circuit comprises a filter configured to filter around a selected spur to which output is coupled a circuit configured to calculate a FFT power spectrum of said selected spur, to which output is coupled a circuit configured to calculate spur estimation as a maximum amplitude of said FFT power spectrum.

In variant embodiments, said calibration unit comprises a sequencer circuit which receives said spur estimation, said sequencer circuit one or more sequence of correction values to be fed to a DAC level control circuit configured to issue a corresponding calibration signal to said output adjustment arrangement configured to adjust an output signal of said internal digital to analog converter based on said a calibration signal.

In variant embodiments, said internal digital to analog converter comprises an arrangement of back-gated MOSFET determining the output of said internal digital to analog converter based on the output digital signal at its input, said output adjustment arrangement being configured to send said calibration signal to the back gates of said back-gated MOSFET to modify their transconductance.

The embodiments described herein also refers to a calibration method of the conversion architecture according to embodiments, comprising: generating a calibration tone with an out-of-band frequency, compared to a baseband signal of said conversion architecture, injecting said calibration tone in the input path of the analog to digital converter; taking the analog to digital converter output signal; estimating the power of a spurious tone selected in the taken output signal; on the basis on the estimated power value, adjusting the output levels of the DAC with a calibration signal to minimize said estimated power value.

In variant embodiments, the operation of, on the basis on the estimated power value, adjusting the output levels of the DAC with a calibration signal to minimize said estimated power value comprises performing a level correction procedure comprising the following steps. For each of the output levels of the DAC output signal of the DAC applying a sequence of increasing correction values of calibrated voltage correction to DAC output levels, measuring for each applied correction value the estimated power of the estimated spur and storing it in a measurement array, at the end of said sequence of increasing correction values finding in said measurement array the measured power of the estimated spur with the minimum value, select the corresponding correction value as calibration value in the calibration signal applied during the conversion operation to set said output level of the DAC output signal.

In variant embodiments, the method comprises selecting an order value and performing subsequent iterations of said calibration signal level correction procedure, updating at the end of each iteration for each level the calibration value in the calibration signal level correction procedure and decreasing the order value, till the order value reaches a threshold at which iterations are stopped and the current calibration value is selected as calibration value in the calibration signal applied during the conversion operation to set said output level of the DAC output signal.

In variant embodiments, the length of said sequence of increasing correction values and a voltage difference between each pair of correction values being proportional to said order value.

In variant embodiments, said decreasing includes dividing by two said order value.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment. Moreover, particular conformations, structures, or characteristics may be combined in any adequate way in one or more embodiments.

The references used herein are provided merely for convenience and hence do not define the extent of protection or the scope of the embodiments.

Here, a self-calibration technique for a conversion architecture with a Sigma Delta converter, in particular for the digital to analog converter, DAC, inside the Sigma Delta Analog to Digital Converter, SD ADC, is described, in which during the calibration period the Sigma Delta converter can be operated on the input signal. Moreover, the conversion architecture and the corresponding method are adaptive to process/temperature variations. The technique is implemented in a standard CMOS process, which is also the best process choice for low power consumption.

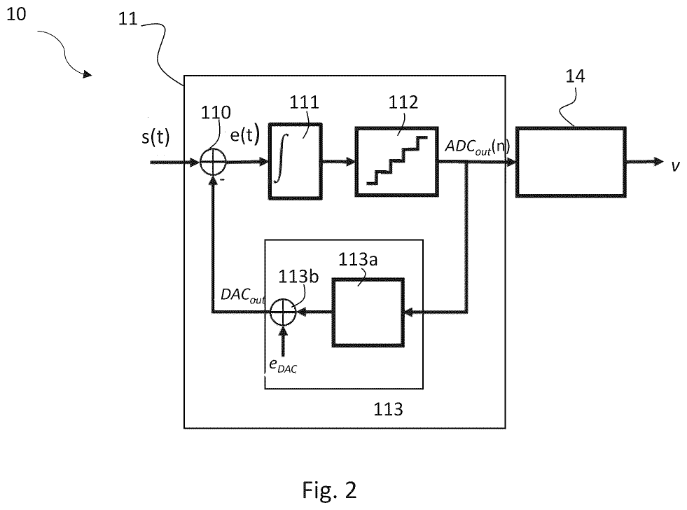

FIG. 2 below shows a continuous time Sigma Delta ADC (CTSD-ADC), comprising, as described below, a non-ideal DAC with mismatches in its output levels, for instance due to differences in the component implementing the conversion.

In FIG. 2 thus with the numerical reference 10 is indicated an electronic circuit architecture comprising a Continuous Time Sigma Delta Analog to Digital Converter, in the following CTSD-ADC, 11, which outputs an output digital signal ADCₒᵤₜ which is filtered by a decimation circuit block, 14, which is implemented by a chain of one or more decimators, outputting a digital output decimated signal. The decimator basically implements a down-sampling of its input signal, keeping one out of a number of samples depending on its driving frequency.

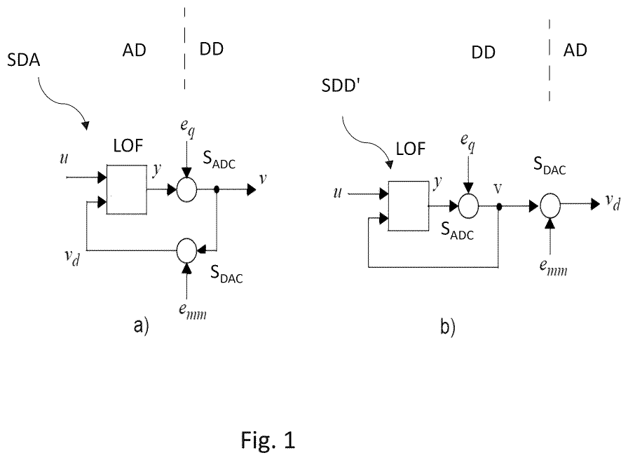

The CTSD-ADC 11 comprises an analog-to-digital converter, i.e., ADC, 112, which digital output ADCₒᵤₜ(n), where n is the number of bits of the digital signal, is fed back through a digital-to-analog converter, i.e., DAC, 113, as DAC analog output signal DACₒᵤₜ, to a difference circuit block 110 calculating an error e(t) between an analog input signal s(t), i.e. varying in time t, and an analog feedback signal corresponding to the analog output signal DACₒᵤₜ of the DAC 113. Such error e(t) is fed as input to the loop filter 11. The DAC 113, as shown, is not-ideal, i.e. contains mismatches, thus it is schematized with an ideal DAC 113a receiving the output digital signal ADCₒᵤₜ and to which analog ideal output in a summation circuit block 113b is added a DAC error, e_{DAC}, substantially corresponding to the mismatch error eₘₘ of FIG. 1a, to obtain the DAC analog output signal DACₒᵤₜ. The ADC 112 usually receives a clock signal for its operation, which is sent by an oscillator, e.g. a PLL (Phase Locked Loop), here not shown, which clock signal is also used, usually frequency divided in one or more divided clock signals by a divider circuit, by the decimator 14, in particular decimator chain.

The Inventors have observed that if a calibration tone is inserted in the loop so that enters the input of the ADC 11 with a proper power level, i.e., compatible with the ADC operation like below saturation level, the mismatches of DAC 113 generate significant spur tones at multiples of the frequency of the calibration tone. Starting from this consideration, the solution provides a conversion architecture comprising a SD ADC and a calibration system which, using a measurement of such spurs, generates calibration signals, e.g. currents/voltages, in the DAC 113 to reduce the mismatches of DAC 113 itself, making a reduction of spurs power level.

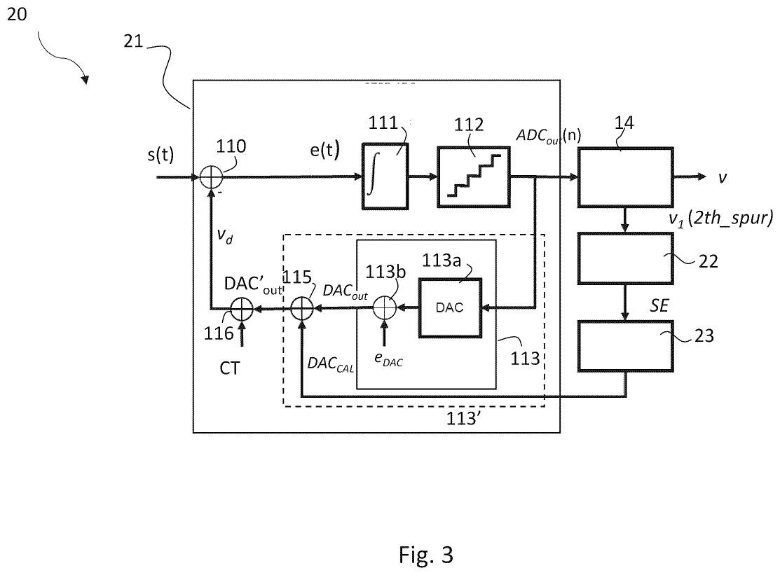

As shown in FIG. 3, where same numeric references indicate same components as in the previous figures, an electronic conversion architecture 20 corresponds substantially to the architecture 10 of FIG. 2, but, in the first place, it further comprises a summation circuit block 116 which receives a calibration tone CT and which is inserted in the feedback loop, i.e., receives the analog output signal DAC′ₒᵤₜ of a digital to analog converter 113′ and the calibration tone CT, outputting an analog signal νd, in particular supplied to the difference circuit block 110, which is the sum of the analog output signal DAC′ₒᵤₜ and of the calibration tone CT, i.e., inserts the calibration tone CT. The conversion architecture 20 also comprises a spur estimation circuit block 22, which takes a decimated signal v1, in the exemplary embodiment the first decimated signal in the decimator chain, as better explained below, from the decimator 14 and it is configured to measure a given spur, 2th_spur, in such decimated signal v₁, i.e., provide a spur power estimation SE, i.e., an estimation of the power of the spurious signal, and a subsequent calibration circuit block 23, which is configured to generate a calibration signal DAC_{cal}, e.g. currents/voltages, to control and correct the output levels of the non-ideal DAC 113. This is represented by a summation circuit block 115 which receives the analog output DACₒᵤₜ of the DAC 113 and sums it with the calibration signal DAC_{cal}, providing its output, a mismatch compensated analog output DAC′ₒᵤₜ to the summation circuit block 116 to be summed with the calibration tone CT, the resulting sum being fed to the circuit block 110 to obtain the error e(t).

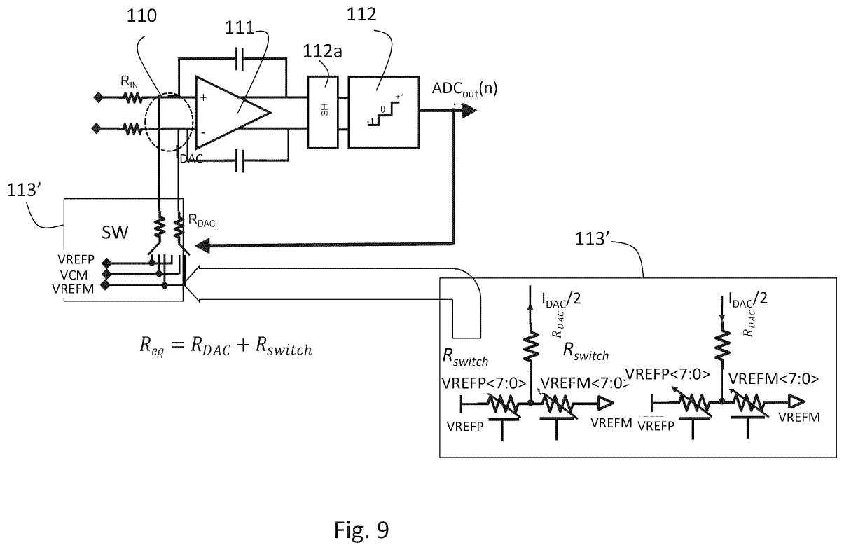

To this regard it is pointed out that the calibration signal DAC_{cal} in FIG. 3 is represented as a correction summed to the output DACₒᵤₜ of the not-ideal DAC 113, i.e., if the output DACₒᵤₜ is represented by a set of voltage values or current values, depending on the type of DAC, the calibration signal DAC_{cal} may comprise corresponding voltages or currents with correction values to be summed to the voltage or current values of the output DACₒᵤₜ to compensate for the mismatches. However, as explained further in the description, the correction can be performed preferably by using the calibration signal DAC_{cal} to modify the voltage or current values of the output DACₒᵤₜ operating on the DAC 113 circuit arrangement. Thus, as shown in FIG. 3, the architecture 10 comprises a compensated DAC 113′, which includes the DAC 113 and the summation circuit block 116, which is representative of applying the calibration signal DAC_{cal} to the DAC 113 to adjust the voltage or current values of the output DACₒᵤₜ either by compensating directly such output DACₒᵤₜ, i.e., by summing or subtracting the calibration signal to the output value, other operations of mixing at the output of the DAC 113 between the output DACₒᵤₜ and the calibration signal DAC_{cal} being not excluded, or by controlling the voltage or current values outputted by the DAC 113 adjusting the operation of internal components of the DAC 113, as shown in FIGS. 9 to 11.

The solution therefore proposes a method to calibrate the architecture described, i.e., estimate and correct DAC mismatches in real time, injecting a tone, i.e., the calibration tone CT, onto the non-ideal DAC 113 output, where the calibration tone CT is taken for example from the decimation chain 14, or also from a separate source.

Then, the method provides to:
generate a calibration tone CT with an out-of-band frequency (e.g. −46 Mhz), compared to the baseband signal (e.g. 17 MHz) of the system, i.e., the input signal s(t) to the converter 20′;
inject the calibration tone CT onto the ADC 112 input to enhance the non-linearities of the DAC 113 avoiding any impact on the base-band signal;
take a version of the ADC 112 output signal ADCₒᵤₜ (e.g. first decimator signal ν₁). For version it is here intended the output signal ADCₒᵤₜ itself or a signal obtained by it, e.g. applying a decimation. This signal is function of the frequency of the harmonic it is desired to attenuate;
estimate the power SE of the spurious signal 2TH_SPUR in the taken output signal, e.g. v₁ (using the spur estimator circuit block 22);
depending on the estimated power SE, act with the Calibration Unit circuit block 23 by compensating the output levels DACₒᵤₜ with a calibration signal DAC_{cal}. This is in FIG. 3 is represented by a sum 116 at the output of DAC 113, as mentioned however this is an equivalent abstract representation, the compensation being in embodiment performed of the on the internal DAC 113a parameters by regulating its internal references (resistances or current thresholds) to minimize the estimated power SE in real time and correct the DAC mismatch.

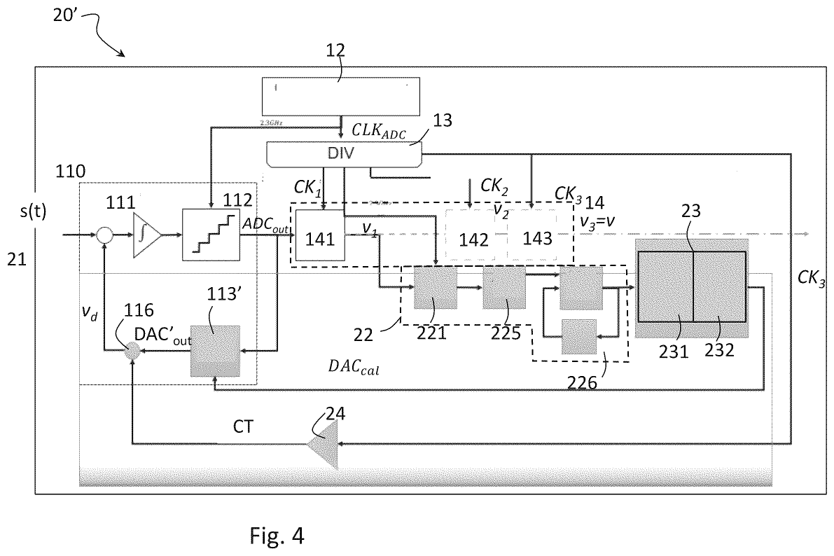

In FIG. 4 it is shown an embodiment 20′ of the architecture 20 of FIG. 3, in which the Continuous Time Sigma Delta Analog to Digital Converter 11 is shown receiving an ADC clock signal CLK_{ADC} with a frequency f_{CLK} from a local oscillator 12, e.g., a PLL oscillator. The output ADCₒᵤₜ of the CTSD-ADC 11 is filtered by the decimation circuit block, 14, which is implemented by a chain of decimators. In the example shown such chain of decimators comprises three decimators in sequence 142, 142, 143. Each decimator 141, 142, 143 is driven by a respective decimator clock signal CK1, CK2, CK3 with respective frequency f_{CLK}/K1, f_{CLK}/K1K2 f_{CLK}/K1K2K3, K1, K2, K3 being constant values, obtained by a divider 13 which receives the ADC clock signal CLK_{ADC} and divides its clock frequency respectively by K1, K1*K2, K1*K2*K3, i.e., each decimator has a frequency which is a submultiple of that of the preceding decimator. The first decimator 141 outputs a first decimated output signal, v₁, which corresponds to the output ADCₒᵤₜ decimated, i.e., down-sampled with the first divided frequency f_{CLK}/K1. A second decimated signal v₂ and third decimated signal v₃, which is the output of the decimation chain 14, are then obtained analogously from the second and third decimator 142 and 143 in series with the first decimator 141 and driven by the respective second and third divided frequency f_{CLK}/K1K2 and f_{CLK}/K1K2K3.

In FIG. 4 the divided clock CK3 is inserted in the path before the input of the ADC 11, namely before the error (e(t) calculation, e.g. in circuit 110, with a proper power level, e.g., a level that is below the saturation maximum voltage of the ADC integrators, set through an amplifier 24, so that the mismatches of DAC 113 generate significant spur tones at multiples of the decimator clock CK3 with respective frequency f_{CLK}/K1K2K3.

By way of example f_{CLK} is 2.3 GHz, f_{CLK}/K1=2.3 GHz/5=466 MHz, f_{CLK}/K1K2=2.3 GHz/25=92 MHz, f_{CLK}/K1K2K3=2.3 GHz/50=46 MHz.

It is also detailed the spur estimation circuit block 22 which receives as input from the decimator 14 the first decimated signal v₁, which is further input to a CIC (Cascade Integrator Comb) decimator 221, which receives a divided frequency f_{CLK}/K4, in the example equal to f_{CLK}/10, i.e. 233 MHz. It is also shown a FFT squarer circuit block 225 which is preceded by a band pass filter, not shown here, centered around the frequency f₂ₜₕₛₚᵤᵣ of the spur 2TH_SPUR received by the decimator 221 in the first decimated signal v₁. A power estimator 226 receives the output of a power spectrum calculation circuit block 225, configured to calculate a power spectrum SSF2 of the spur 2TH_SPUR, and computes a spur estimation value SE, i.e., calculates the maximum amplitude of the power spectrum SSF2. The spur estimation SE is sent to the calibration unit 23, which comprises a sequencer 231, followed by a DAC level control circuit 232 issuing the calibration signal DAC_{CAL}, i.e. a set of currents and/or voltages which values change the output levels of the calibrated DAC 113′, which is indeed shown here as a whole circuit block or circuit, producing the compensated output signal DACₒᵤₜ.

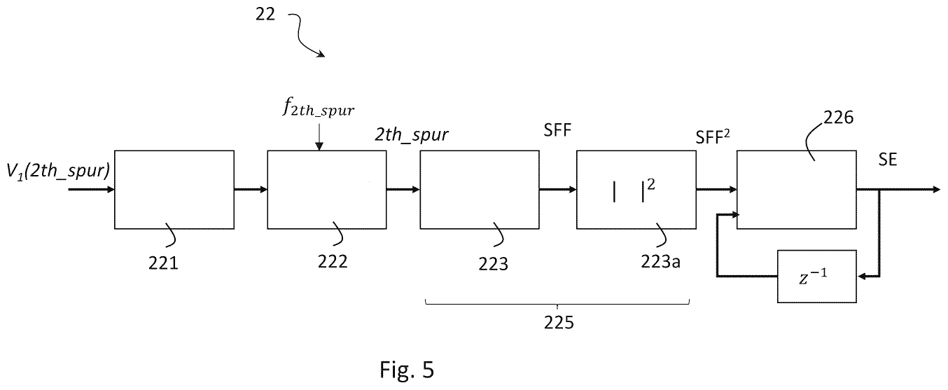

In FIG. 5 it is shown an embodiment of the spur estimator 22, which comprises a band pass 222 filter, e.g. a discrete FIR filter, centered around the frequency f₂ₜₕₛₚᵤᵣ of the spurious tone or spur 2TH_SPUR received by the first decimator 141 in the taken signal, in the example first decimated signal ν₁, and a FFT circuit block 223 configured to perform a Fast Fourier Transform of the filtered spurious tone, then the output FFT signal SFF is fed to a square calculation circuit 223 which calculates the squared FFT, SFF², of the spectrum SFF, substantially the power spectrum of the filtered spurious tone 2th_spur at frequency f₂ₜₕₛₚᵤᵣ, of the FFT, followed by a power estimator 226, supplying the spur estimation SE. Circuit blocks 223 and 223a correspond to the FFT power spectrum circuit block 225. The CIC (Cascade Integrator Comb) decimator 221 is inserted, as in the example shown, before the band pass filter 222, to improve the estimate. It is noted that decimator 221 may be optional.

Substantially, the signal taken from the decimator 14, in the example first the decimated signal v₁, is filtered around the selected spur, e.g. the second spur, then the FFT circuit blocks 223, 223a, corresponding together to circuit block 225, obtain the FFT power spectrum SFF² of the spur 2th_spur, in particular the FFT squared, then the maximum amplitude of the FFT power spectrum SFF² is calculated in the power estimator 22, which is configured to find the maximum amplitude of such power FFT power spectrum SFF², in particular by computing its absolute value which is compared with the previous maximum value by a delay line.

Thus, based on the above, the solution described is directed to a conversion architecture, e.g., 20, 20′ comprising a Continuous Time Sigma Delta Analog to Digital Converter, e.g., 11 comprising a loop filter, e.g., 111 followed by an analog to digital converter, e.g., 112 and a feedback loop, e.g., specifically a calibrated converter feeding back the output, e.g., output signal v or ADCₒᵤₜ, of said analog to digital converter, e.g., 112 through an internal digital to analog converter, e.g. 113′ to obtain, e.g., by the difference circuit block no, an error signal, e.g., e(t), with respect to a input signal, e.g., u, s (t), which is fed to said loop filter, e.g., in, an output digital signal, e.g., ADCₒᵤₜ of the analog to digital converter, e.g., 112 being fed to a decimation chain of decimators, e.g., 14, a local oscillator, e.g., 12 feeding a clock signal, e.g., CLK_{ADC} to said analog to digital converter, e.g., 112, and, through a frequency divider, e.g., 13, to said chain of decimators, e.g., 14, wherein said conversion architecture, e.g., 10 further comprises:
a circuit arrangement, e.g., configured to obtain, e.g. through the amplifier 24 setting the level, a calibration tone, e.g., CT by a divided frequency, e.g., CK3 outputted by said frequency divider, e.g., 13, to said chain of decimators, e.g., 14 and inject said calibration tone, e.g., CT in said feedback loop, e.g., in the sum circuit block 116, in particular in the input path of said analog to digital converter, e.g., 112, this meaning that it could be also injected downstream the sum circuit block 110 for instance,
a calibration arrangement, e.g., 22, 23 which comprises
   a spurious tone estimation circuit, e.g., circuit 22, configured to obtain an estimation, e.g., SE of the power of a spurious tone, e.g., 2th_spur in said output signal, e.g., v based on a decimated signal, e.g., v₁ taken in said decimation chain, e.g., 14, and
   a calibration unit, e.g., 13 receiving said estimation, e.g., SE of the power of a spurious tone, e.g., 2th_spur and configured to send a calibration signal, e.g., DAC_{CAL} as function of said estimation, e.g., SE of the power of a spurious tone to said digital to analog converter, e.g., 113′, which comprises an output adjustment arrangement, e.g., 115; 1131, 1132 configured to adjust an output signal, e.g., DAC′ₒᵤₜ of said internal digital to analog converter, e.g., 113 based on said a calibration signal, e.g., DAC_{CAL}.

The choice of the calibration tone CT must be made so that it falls outside the system band or base band, e.g., the frequency of the input signal which the SD-ADC converter can handle. In the example here shown it is 17 MHz. For example, a possible choice is a tone at the sampling frequency of the last decimator 143, as shown in FIG. 4, i.e., f_{CLK}/K1K2K3=2.3 GHz/50=46 MHz. It is important that the calibration tone CT has a high purity, for this reason the choice of the example takes the signal of the VCO of the PLL of the local oscillator 12, through the divider 13. The spur chosen for calibration must be the second or at most the third in frequency among those generated.

Now the operation of the calibration unit 23 is described.

Considering a DAC 113 whose analog output levels, e.g., voltage output levels, are a set of levels [0 . . . Nₗₑᵥₑₗₛ] with Nₗₑᵥₑₗₛ+1 being the number of output analog levels of such DAC 113, Nₗₑᵥₑₗₛ+1=2^{Nbit}, Nbit being the number of input bits of the DAC 113, to such output levels [0 . . . Nₗₑᵥₑₗₛ] corresponds a vector DAC_{ideal}_{ₒᵤₜ} of ideal output voltages of the DAC 113,

$${DAC}_{{ideal}_{out}} = - {V}_{ref} : {V}_{step} : {V}_{ref}$$

where a voltage step, i.e. the step of the DAC 113, is defined as

$${V}_{step} = \frac{2 {V}_{ref}}{{N}_{leνels}}$$

and V_{ref} is a reference voltage of the DAC 113.

Due to the mismatches, the voltage levels of the vector DAC_{ideal}_{ₒᵤₜ} present an error that it can be considered distributed in a Gaussian way and whose standard deviation is equal to a percentage lpₘᵢₛ of the value of the step Vₛₜₑₚ.

Thus, the actual output of the DAC 113 DACₒᵤₜ can be indicated as:

$${DAC}_{out} = {DAC}_{{ideal}_{out}} + {lp}_{mis} {V}_{step} \cdot randn$$

randn indicating a random value.

It can be assumed that the error of one level among the DAC output levels [0 . . . Nₗₑᵥₑₗₛ] is independent of the adjacent ones.

The calibration unit 23 does not know and cannot directly measure the values of the actual output of the DAC 113 DACₒᵤₜ.

As the only measure of the effect of the calibration, is available the spur estimation SE, i.e., the measurement of the power of the second spur tone, called f₂ₜₕₛₚᵤᵣ, determined by the calibration tone CT, which is injected in the feedback path and thus manifest itself in the output of the ADC, ADCₒᵤₜ, which is brought to the spur estimator 22 from the decimator 14, in the example the first decimated output signal, v₁, is taken. For this reason the frequency of the second spur f₂ₜₕₛₚᵤᵣ is double the frequency of the calibration tone CT.

The aim of the calibration unit 23 is to find a DAC calibration signal DAC_{CAL} such that the sum DACₒᵤₜ+DAC_{cal} minimizes the power level of the second spur tone f₂ₜₕₛₚᵤᵣ.

The procedure described below, implemented by the calibration unit 23, establishes the sub-optimal DAC calibration DAC_{CAL} values, outputted by the calibration unit 23, level by level. This calibration procedure is repeated several times, called calibration iterations, until there is no longer an improvement in the mismatch level.

Substantially, a calibration method of the architecture 20 or 20′ comprise a calibration value calculation procedure in which, for each of the DAC output levels, e.g. Nₗₑᵥₑₗ+1 DAC output levels, of the output signal DAC_{OUT}, comprises: applying a sequence of increasing test values of calibrated voltage or current corrections to the corresponding DAC output voltage or current (r), measuring for each test value of calibrated voltage correction which is applied a power of the estimated spur SE and storing it in a measure array, M, at the end of said sequence finding in said measure array M the measured power of the estimated spur SE with the minimum value, select the corresponding test value of calibration voltage correction as calibration value in the calibration signal DAC_{cal} corresponding to said analog output level.

The method provides then an iterative refinement procedure comprising: setting an order value Order, a number of iterations performed by the iterative refinement procedure being function of said order value, performing subsequent iterations of said calibration value calculation procedure, updating at the end of each iteration for each level the calibration value in the calibration signal DAC_{CAL} and decreasing the order value Order, till the order value Order reaches a threshold at which iterations are stopped and the current calibration values in the calibration signal DAC_{CAL} maintained, the length of said sequence and a voltage difference step_{cal} between each pair of test values of calibrated voltage correction in the sequence being proportional to said order value Order. In particular, said decreasing the order value Order includes dividing by two said order value Order.

Thus, at each calibration iteration, a calibration unit 23 sequencer, which implements the algorithm, starting from the first level of the actual DAC output DACₒᵤₜ, applies the correction currents/voltages in the calibration signal to the DAC 113 output following the equations below:

max_{voltage}_{_{ctrl}}≥3lpₘᵢₛVₛₜₑₚ A maximum voltage max_{voltage}_{_{ctrl}} which corresponds to the range of voltage correction values for the calibration is set as greater equal than three time lpₘᵢₛVₛₜₑₚ, which is three time the standard deviation of the output levels of the DAC output signal DACₒᵤₜ, i.e. the known 36 criterion, times the output voltage step Vₛₜₑₚ of the output of the DAC 113, which, as mentioned, depends on the number of output levels Nₗₑᵥₑₗ+1, and the reference voltage V_{ref}.

Then an initial calibration step step_{cal} is calculated as:

$${step}_{cal} = \frac{{max}_{{voltage}_{ctrl}}}{max ( \frac{{order}_{cal} - 1}{2 , 2} )} \qquad ( 1 )$$

i.e., the calibration step step_{cal} is the ratio of the maximum voltage max_{voltage}_{_{ctrl}} i.e., the calibration range, divided by the maximum between 2 and the half of the calibration order Order_{cal}-minus one. Since the maximum voltage max_{voltage}_{_{ctrl}} is ≥3lpₘᵢₛVₛₜₑₚ, thus the value of the calibration step step_{cal} is half the maximum voltage max_{voltage}_{_{ctrl}} or lower, depending on the calibration order Order_{cal} value, i.e., proportional to the standard deviation lpₘᵢₛ*Vₛₜₑₚ, specifically 3/2 or lower depending on the calibration order Order_{ca}i value.

Equation (1) sets the initial value of the calibration step step_{cal}, which however is divided then in the example by three at the end of each calibration step when the value of the calibration order Order_{cal} is instead halved, as shown in the example of the Sequencer algorithm below. As indicated there the value of the calibration step or step_{cal} or step and of the order Order_{cal} or Order are updated each time the algorithm is performed on the whole set of levels, i.e., as explained below, for each output level l from 0 to Nₗₑᵥₑₗ, with a given value of order Order and step Step, a procedure is performed, which, as detailed in the Sequencer routine below, for each level applies the correction for the mismatch, measuring then the power of the spur tone SE is measured, and finding the minimum absolute value of the measure array M(t) and its index stored as minimum value min_val and minimum index min_index, then changing the correction table Corr_table for t=min_index with the minimum value min_val, i.e., the correction value in the sequence Steps_{Table} which determines the minimum value of the power of the spur.

A sequence StepS_{table} of correction values for a given output level of the DAC output signal is then:

$${Steps}_{table} = [ \begin{matrix}\frac{- ( {Order}_{cal} - 1 )}{2} {step}_{cal} \\ {step}_{cal} \cdot ones ( 1 , \frac{( {Order}_{cal} - 1 )}{2} - 1 ) \\ 2 {step}_{cal} \\ {step}_{cal} \cdot ones ( 1 , \frac{( {Order}_{cal} - 1 )}{2} - 1 ) \\ \frac{- ( {Order}_{cal} - 1 )}{2} {step}_{cal}\end{matrix} ] \qquad ( 2 )$$

i.e., the sequence ranges from

$$\frac{- ( {Order}_{cal} - 1 )}{2} {step}_{cal} to - \frac{( {Order}_{cal} - 1 )}{2} {step}_{cal}$$

increasing of calibration step step_{cal} at each subsequent correction value in the sequence, skipping the zero correction value, i.e., the sequence passes from a correction of +step_{c}al to a correction of −step_{cal}. The last correction value

$$\frac{- ( {Order}_{cal} - 1 )}{2} {step}_{cal}$$

has the minus sign, since it is the correction value which measures at the center point, i.e. zero correction value, which was skipped. Such center, which corresponds to the actual level of the DAC output DACₒᵤₜ is thus the last measure.

In equation (2) the sequence of correction values is shown as transposed vector, i.e. a column, for space reasons, but it can be regarded also an array, i.e. an array of a row representing the sequence of correction values.

This sequence Steps_{table} of correction values is applied for a specific level among the Nlevel+1 output levels of the DAC 113 and for a specific calibration order Order_{cal} value. The length of the sequence Steps_{table} depends on the value of the calibration order Order_{cal} value, in particular is equal to the calibration order Order_{cal} value.

Then a correction table Corr_{table} is obtained as sum of the sequences Steps_{table} for each of the Nₗₑᵥₑₗₛ+1 output level of the DAC 113 as a sum over the number of output Nₗₑᵥₑₗₛ and refined a number of times defined by the calibration order Order_{cal},

$${Corr}_{table} = {\{ {\sum }_{k = 0}^{n} {Step}_{table} ( k ) \}}_{n = 0 : {Order}_{cal}} \qquad ( 3 )$$

Step_{table}(k) is the k-th element, i.e. the k-th test correction value in the sequence Steps_{table}. Thus a correction table Corr_{table} for a given output level of the DAC 113 is a set of summations of correction sequences Steps_{table} with n+1 correction values, where n is set by the calibration order Order_{cal} value, i.e., is the sum of sequences correction sequences Steps_{table} of different lengths depending on the calibration order Order_{cal} value as said. The correction table Corr_{table} depends on the calibration order Order_{cal} value, but the calibration order Order_{cal} value during the iterations loop decrease because at each iteration is divided by two.

The Calibration Order, Order_{cal} is the number of voltage or current test points of test points, i.e., number of measures, around a DAC 113 level. Thus, the time to calibrate a single level is hereafter called Level Time Calibration (LTC).

Generally, at the first calibration iteration the Calibration Order Order_{cal} is set as an odd number greater than 15. At subsequent calibration iterations, the Calibration Order Order_{cal} is halved and as consequence the calibration step step_{cal} is also reduced.

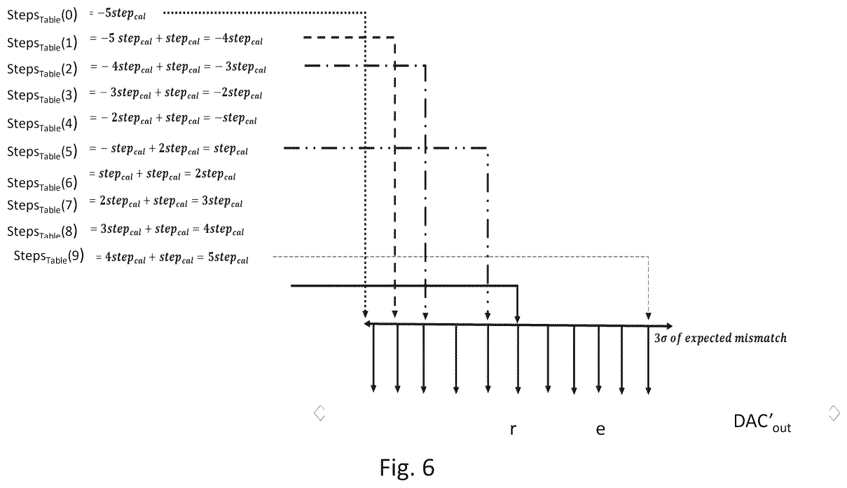

Thus, the calibration method, performing the corrections of the DAC mismatch errors, of the conversion architecture, e.g. 20, 20′, may be summarized as comprising the steps of:
generating—e.g. by taking a clock signal, e.g. CK3, with a divided frequency with respect to that of the oscillator, e.g., 12, feeding its clock signal CLK_{ADC}, to the ADC 112
a calibration tone, CT, with an out-of-band frequency, compared to a baseband signal of said conversion architecture e.g. 20, 20′,
injecting such calibration tone CT in the input path, e.g., downstream the calibrated ADC 113, of the analog to digital converter 112;
taking a version of the analog to digital converter 112 output signal, in the example a decimated version ν₁ of it;
estimating, by the estimator circuit 22, the power, e.g. the estimation SE, of a spurious tone, in the example the second spur 2th-spur although other spurs may be chosen, selected in the taken version of the output signal, e.g., v₁;
on the basis on the estimated power, e.g., SE, value, adjusting, by the calibration unit 23, the output levels, e.g. the levels of the analog output signal DAC′ₒᵤₜ of the calibrated DAC 113′, with a calibration signal DAC_{cal}, to minimize said estimated power SE value, e.g., by the exemplary procedure performed by the sequencer 231 described with the pseudo-codes below and FIGS. 6 to 8.

An example of procedure performed by the sequencer 231, named Sequencer, along with its sub-procedures or sub-routines, new_Corr_table, apply_change, measure_2LO_tone are resumed below in a pseudocode.

The main procedure Sequencer determines the correction table Corr_{table} receiving as input the calibration order Order, an odd integer, the number of input bits Nbit of the DAC 113. Also the procedure Sequencer receives time values for correct operation, a hold time Thold, i.e. a time to wait for the settling of the system after applying a correction, and a measure time Tmeasure, i.e., a duration of the measure of the spur power in the circuit 22. Thus, as an example, the corresponding pseudocode may be:

```
Sequencer
input :Order (odd integer), Step (the initial step voltage) N_{bit} (bit of DAC level control), Thold
(Hold time), Tmeasure (measure Time)
Corr_{table} ← new_Corr_table(Order, N_{bit})
while Order>=2 do
  for l=0 to Nlevel do
    MT ← 0
    for t=0 to Order do
      corr_{word} ← Corr_{table}(t)
      apply_change(l,corr_word,Thold)
      MT(t) ← measure_2LO_tone(Tmeasure)
  end for
  min_val, min_index ← min(abs(MT))
  apply_change(l,Corr_{table}(min_index),Thold)
  end for
  Order ← Order/2
  Step ← Step/3
  Corr_{table} ← new_Corr_table(Order, Step, N_{bit})
end while
```

The sub-routine new_Corr_Table, which receives as input within the procedure Sequencer the calibration order Order, an odd integer, the number of input bits Nbit and outputs the correction table Corr_{table}, corresponds to apply equations (1), (2), (3) above:

```
new_Corr_table
input : Order_{cal} (odd integer), step_{cal}(the voltage step), N_{bit} (number of
bits of DAC level control)
output : Corr_{table}
  ${Steps}_{table} = [ \begin{matrix}\frac{- ( {Order}_{cal} - 1 )}{2} {step}_{cal} \\ {step}_{cal} \cdot ones ( 1 , \frac{( {Order}_{cal} - 1 )}{2} - 1 ) \\ 2 {step}_{cal} \\ {step}_{cal} \cdot ones ( 1 , \frac{( {Order}_{cal} - 1 )}{2} - 1 ) \\ \frac{- ( {Order}_{cal} - 1 )}{2} {step}_{cal}\end{matrix} ]$
    $C o r {r}_{t a b l e} ← {\{ {\sum }_{k = 0}^{n} {Step}_{t a b l e} ( k ) \}}_{n = 0 : Order}$
```

The subroutine apply_change receives as input the current level 1 among the output levels of the DAC 113, which is set by the procedure Sequencer, a correction word variable Corr_word also set by the procedure Sequencer (corresponding to the correction table Corr_{Table} at a current value of the calibration order Order), and also the hold time Thold.

The corresponding exemplary pseudocode is:

apply_change
input :level, Corr_word, Thold
DAC_register(level) ←Corr_word
Wait(Thold)

Then, the spur measurement sub-routine measure_2LO_tone, just measures the power SE of the spurious signal in the taken output signal, e.g. ν₁, by the estimator circuit block 22, thus is:

measure_2LO_tone
input :Tmeasure
output: measure
Wait(Tmeasure)
measure ← Max output values

Thus, in the routine Sequencer performed by the circuit 23, the following procedure is performed while the calibration Order is greater equal than two. As a first step the correction table Corr_{table} is set as array or matrix, using the sub-routine new_Corr_table which calculates equations (1), (2), (3), which as shown are function of the calibration order Order and of the number of bits Nbit, corresponding to n and outputs the correction table Corr_{table}. Thus, a series of sequences Steps_{table} of correction values proportional to the calibration step Stepcal (with the exception of the zero correction) where the length of each sequence Steps_{table} and number of sequences in the series, i.e., correction table Corr_{table}, depends from the calibration order Order, is stored. As said the length of a sequence Steps_{table} corresponds to the value of the calibration Order, while the number of sequences depends, if the calibration order Order, on how many subsequent operations round_odd (Order/2), i.e., rounding to the nearest odd integer the order Order halved by two are required to reach zero. For instance, Order=25 means 5 sequences, i.e., iterations, while Order=15 means for 4 iterations.

Then for each output level l from 0 to Nₗₑᵥₑₗ a procedure is performed, in which a mismatch measure array MT is set to zero, then for each sequence index value t between zero and the current calibration order Order is performed in which in the correction word corr_word, i.e., the current correction value for the current value of the sequence index value t (also indicated with k elsewhere) is stored in an array DAC_register with an index corresponding to the level l. The value is stored in the register array DAC_register is representative of the correction being applied by the DAC 113′ for that level l in its output signal DAC′ₒᵤₜ. The change applying sub-routine apply_change is performed, i.e., a correction for the mismatch is applied to level l. Then the hold time Thold is waited, long enough to allow the corrections to propagate through the loop, through circuit blocks 11, 112, to the output ADCₒᵤₜ, then the power of the spur tone, i.e. second spur tone, SE is measured, at the estimator 22, for the duration of the measure time Tmeasure. Then its value is stored in the measure array M(t), t being the index of the correction value in the sequence Steps_{Table} for the current level l. When the correction values from zero to order Order have been all applied and the measure array M(t) filled with the corresponding measured values of the spur SE, the minimum absolute value of the measure array M(t) and the value of index t in the array are stored as minimum value min_val and minimum index min_index. Subsequently the change application procedure apply_change is applied with the current output level l and the correction table Corr_table for t=min_index, i.e., the correction value in the sequence Steps_{Table} which determines the minimum value of the power of the spur.

The steps of the spur minimization procedure are repeated for each of the analog output levels 1 from 0 to Nₗₑᵥₑₗ. At the end of the repetitions on all the levels l, the order value Order is halved (and rounded to the greatest odd integer) and the correction table Corr_{table} is again set as array or matrix, using the sub-routine new_Corr_table with the new, halved, valued of calibration order Order and the number of bit Nbit, which is unchanged, storing it in the correction word corr_word.

As mentioned the whole procedure is performed, till the value of the calibration order value Order is greater equal than two.

Thus, during a Level Time Calibration LTC, for each step of modified voltage/current in the DAC 113, the maximum RMS power of the tone f₂ₜₕ_{ₛₚᵤᵣ} is measured and this value is stored in a memory (e.g., array M(t)). At the end of the time LTC, when all the steps of the tests for a given level have been performed, the step value that gave the lowest value of the tone f₂ₜₕ_{ₛₚᵤᵣ} power is applied as a correction value and begins to be part of the calibration signal DAC_{cal}.

During the subsequent calibration iterations, this value is gradually corrected more and more with values increasingly closer to the ideal value: indeed, during the successive calibration iterations, the voltages points, where the correct value of calibration is searched, are increasingly closer to the previously found point.

To better understand how the sequencer 231, e.g. the procedure Sequencer operates the calibration, it is considered a simple case of a DAC 113 with only one level mismatched. In FIG. 6 it is depicted what happens during the calibration. On the horizontal axis is indicated the output voltage DAC′ₒᵤₜ of the calibrated DAC 113′, while the arrow pointing down from the horizontal axis represents spurs originated by the sequence of correction values Steps_{Table}(k) with calibration order Order=11, thus k goes from 0 to 9, and the sequence goes from Steps_{Table}(k)=−5*Step_{cal} to +5*Step_{cal} increasing of one calibration step Step_{c}al at a time, with the exception of Steps_{Table}(5), i.e. the central element of the sequence, which is increased of 2*Step_{cal} to avoid applying a zero correction. In this example the real level, indicated with r, and corresponding to zero correction, is below the expected one, indicated with e. As mentioned, at the start of calibration, in the first measure a negative voltage (correction sequence element Steps_{Table}(0)) equal to −5*step_{cal} is added to the real level and a measure of the power SE at the second spur frequency f₂ₜₕ_{ₛₚᵤᵣ} is performed. This measure is stored in the memory table MT, as explained with reference to procedure Sequencer. From the second measure to the 5^{th} one, the added voltage step is step_{cal} and the result of power estimation are stored in the measure array MT. At the 6^{th} measurement, the voltage added is equal to 2step_{cal} and the power of the spur after the real level r is estimated. At the end, a voltage of −5*step_{cal} is added and power SE at the second spur frequency f₂ₜₕ_{ₛₚᵤᵣ} linked to the real level r is measured and stored. Hence, the minimum of the measure array MT values is searched and in the case of the example the minimum is found at the 8^{th} measure time (k=7, i.e., the minimum index min_index is 7) and is very near to the expected value e. In the successive iterations, i.e., with Order=7 this correction value is further adjusted.

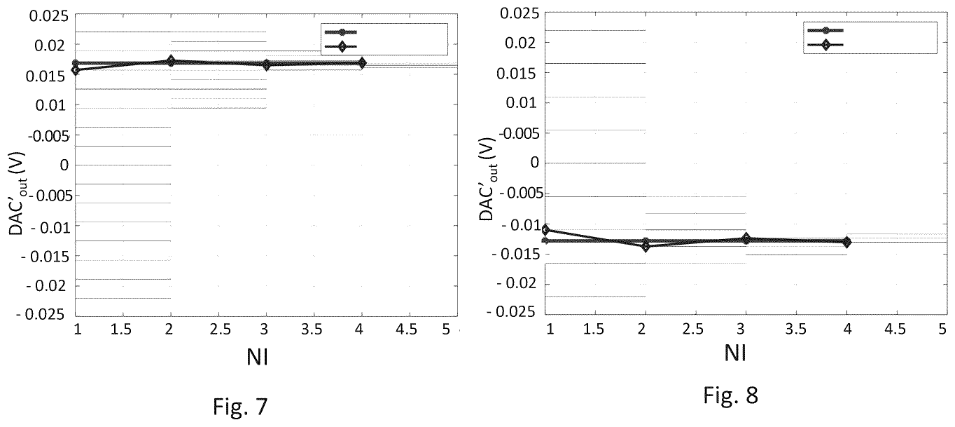

FIG. 7 shows a case of a calibration of the central level of the DAC. Calibration order Order is 15. Mismatch error is 4%. In the FIG. 8 it is shown the test with a Calibration order Order equal to 9. On the horizontal axis is the ordinal number of the iteration NI, while on the vertical axis is the DAC voltage output, i.e. DAC′ₒᵤₜ. The line with the full circles is the mismatched output level of the DAC 113, while the line with the diamonds is the correction control, i.e. the calibration signal DAC_{CAL} for that level. For instance in FIG. 7 it can be seen that the number of correction values Steps_{Table}(k) and the calibration order Order decrease with the subsequent iterations NI, in a voltage range which shrinks around the mismatched level to correct.

Thus, based on the pseudocode examples above and FIGS. 6 to 8 the operation of, on the basis on the estimated power, e.g., SE value, adjusting, e.g., 23 the output levels, e.g., DAC′ₒᵤₜ of the DAC, e.g., 113′ with a calibration signal, e.g., DAC_{cal} to minimize said estimated power, e.g., SE value comprises performing a level correction procedure comprises the steps of:

for each of the output levels, e.g., the Nₗₑᵥₑₗ+1 output levels of the DAC 113′ output signal, e.g., DAC′ₒᵤₜ of the DAC, e.g., 113′ applying a sequence of increasing correction values, e.g., Step_{table}(k), of calibrated voltage correction to DAC output levels, measuring for each applied correction value, e.g., Step_{table}(k) the estimated power SE of the estimated spur, e.g., 2th_spur, and storing it in a mismatch measurement array, e.g., M(t),

at the end of said sequence of increasing correction values, e.g., Step_{table}(k), finding in said measurement array, e.g., M(t), the measured power, i.e. estimate SE, of the estimated spur, e.g., 2th_spur with the minimum value, selecting, e.g. i.e. setting the minimum index min_index, the corresponding correction value, e.g., Step_{table} (min_index), as calibration value in the calibration signal, e.g., DAC_{cal}, applied during the conversion operation to set said output level of the DAC output signal, e.g., DAC′ₒᵤₜ. Thus, the adjustment procedure at the end sets a correction value, i.e. fixes it, in the correction table Corr_{Table}, which contains the correction values sent in the calibration signal DAC_{cal} during operation of the converter, i.e. to have a converter operating with minimum mismatch error. The calibration may be always operating or it may be performed during normal operation, triggered by the occurrence of a command or a time interval.

The previous procedure can be performed once, setting the minimum index and the correction value or values sent in the calibration signal DAC_{cal} during operation of the converter, however the method provides an iteration procedure to refine the correction values, comprising selecting an order value, e.g., Order or Order_{Cal}, and performing subsequent iterations of said calibration signal level correction procedure, updating at the end of each iteration for each level the calibration value in the calibration signal level correction procedure and decreasing the order value, e.g., Order, till the order value, e.g., Order reaches a threshold at which iterations are stopped and the current calibration value, e.g., Step_{table} (min_index) is selected as calibration value in the calibration signal, e.g., DAC_{cal} applied during the conversion operation to set said output level of the DAC output signal, e.g., DAC′ₒᵤₜ.

In particular, a length of said sequence of increasing correction values, e.g., Step_{table}(k), and an output signal, e.g., voltage, difference, e.g., Step_{cal} between each pair of correction values, e.g., Step_{table}(k), being proportional to said order value, e.g., Order.

In particular, said decreasing includes dividing by two said order value, e.g., Order. Also the Order is chosen as an odd integer.

Regarding the implementation actuation of correction, to simplify, with reference to FIG. 9, it is a considered a 1^{st} order Sigma Delta ADC: the DAC 113′ output is a current I_{DAC}. The DAC 113′ is of the resistive type, comprises a series of resistors R_{DAC} with switches SW controlled in their opening and closing status to couple the resistors R_{DAC} to either a positive reference voltage VREFP or to a ground voltage VREFM. Coupling to a common mode voltage VCM is also possible. The digital input, i.e. ADCₒᵤₜ(n) selects the coupling of each resistor R_{DAC} to obtain the desired value of the DA output current I_{DAC}, depending on the applied voltage, e.g. VREFP, and an equivalent voltage R_{eq}=R_{DAC}+R_{switch}. If the resistors R_{DAC} are not perfectly equal, a DAC mismatch in the output currents I_{DAC} is generated. To correct this mismatch of the resistor R_{DAC}, switch resistors R_{switch} have been added according to the solution: controlling the values of the switch resistors R_{switch} it is possible to have equivalent resistances R_{eq}=R_{DAC}+R_{switch} that are near to the ideal equality. FIG. 9 shows the proposed architecture for an 8 bit DAC, where the loop filter 11 and the ADC 112 including its sample and hold circuit 112a feed bac an ADC 113 comprising such resistors R_{DAC} with switches SW commanded by the digital input, i.e. ADCₒᵤₜ(n). Reference voltage is a differential voltage with a maximum reference voltage VREFP and a minimum reference voltage VREFM. In the magnification of a part of the DAC 113 in FIG. 9 it can be seen that each resistor R_{DAC} is coupled through two switches SW, one to the maximum reference voltage VREFP, which can be for instance+V_{REF}, and the other to the minimum reference voltage VREFM, which can be for instance−V_{REF}. Each switch SW has a variable switch resistance R_{switch}.

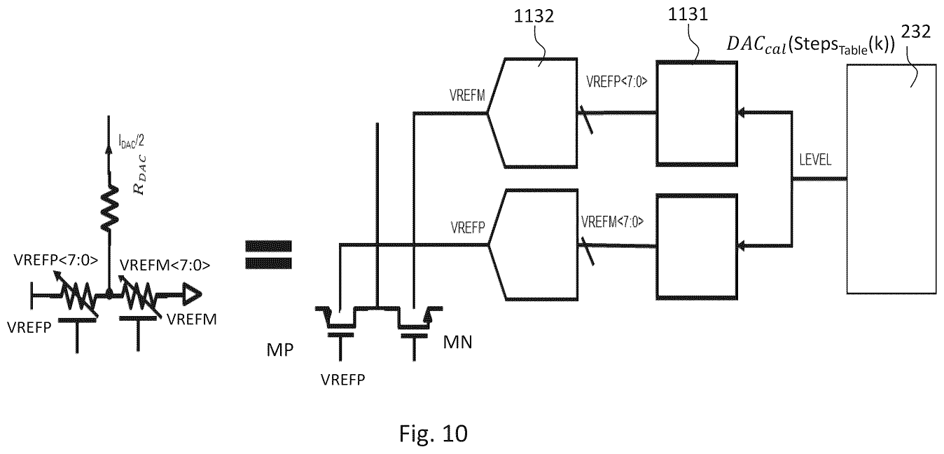

As shown in FIG. 10, an implementation can provide that the DAC level control 232 provides a correction value Steps_{Table}(k), e.g., as shown the calibration step step_{cal} or a multiple of it, as calibration signal DAC_{cal}, which is provided as digital signal, this being correction value for a specific level, as shown for instance in FIG. 6.

The correction value in the calibration signal DAC_{cal} is sent in parallel to two decoder 1131, which decode voltage levels, one providing a digital maximum reference voltage correction, e.g. 8 bit VREFP<7:0>, i.e. a 8 bit value between 0 and VREFP, and the other providing a digital minimum reference voltage, VREFM<7:0>, an 8 bit value between 0 and VREFM, then two respective DAC 1132 convert them in the corresponding analog maximum control voltage VREFP and minimum control voltage VREFM, which are applied to the back gate of respective FD-SOI n MOSFET MN and a p MOSFET MP.

Using the FD-SOI technology the variable switch resistance R_{switch} is obtained through the back gate usage. To each FD SOI MOSFET, n MOSFET MN and a p MOSFET MP it can be applied a respective back gate voltage, VBBN and VBBP. Applying the analog control voltages VREFP and VREFN as back gate voltages, VBBN and VBBP, is it possible to change, in a way per se known their drain source transconductance, gm_{DS} generating in this way a controlled resistance, i.e., switch resistance R_{switch}, in series with the resistor R_{DAC}. In particular, by varying through the digital words VREFP<7:0> and VREFM<7:0> the bulk voltage of the n MOSFET MN and a p MOSFET MP is possible to tune their threshold voltage Vth of the transistors as shown, changing thus their drain source transconductance, gm_{DS}.

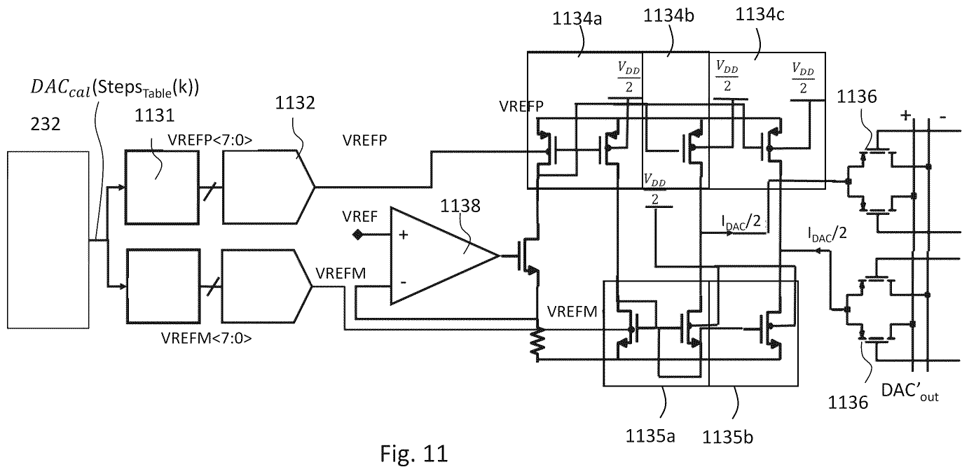

In FIG. 11 it is shown the implementation in a current steering DAC, which in a way per se known includes a plurality of current generators, embodied by current mirrors with p MOSFET, 1134a, 1134b, 1134c, in parallel, which voltage supply is the voltage supply VDD, while the bulk electrode of their MOSFET is coupled to the voltage supply VDD/2, with the exception of the bulk electrode of the input MOSFET of mirror 1134a, the one coupled to a buffer amplifier 1138, which is coupled to the maximum reference voltage VREFP, and current mirrors 1135a, 1135b, coupled to the output of mirror 1134a and having their output in common with the output of mirrors 1134b and 1134c respectively, with the input n MOSFET of mirror 1135a having the bulk electrode coupled to the minimum reference voltage VREFM and the other to VDD/2. Switches 1136 couple the outputs an analog output current, I_{DAC}/2, supplied by the MSB or LSB current generators, to the differential analog output signal DAC′ₒᵤₜ. A reference signal VREF is brought through a buffer amplifier 1138. The operation of such circuit, where each current generator is controlled by a bit of the input digital word, contributing a given amount of current to the output current IDAC, is in general known. The relevant aspect is that the mismatch of MOSFETs in the current mirrors generate a mismatch in the output currents I_{DAC}. Thus, according to the solution here described, the MOSFET in the current mirrors are FD SOI MOSFET, either n or p, with back gate voltage, like in FIG. 9. Therefore, also in this case adjusting the back gate voltage of the MOSFETs the mismatch can be corrected. As shown, the same correction chain comprising circuits 232, 1131, 1132 provides the correction voltages VREFP and VREFN to the back gate of the MOSFET n and p respectively in the current mirrors.

The back gates of the mirror MOSFET are supplied to Vdd/2 (half of the digital supply voltage), and the back gate of diode Mos are driven by the correction DAC, i.e. the chain of circuits 232, 1131, 1132. By way example, a resistance variation of the n MOSFET and p MOSFET e.g. +/−2.5% is obtainable changing the voltages VREFP and VREFM, i.e. the back-gate voltages, this being able to recover an overall mismatch (static and dynamic) of the same amount.

Thus, regarding this aspect, summarizing the conversion architecture here described, e.g., 20, 20′, may perform the calibration by an internal digital to analog converter, e.g. the converter 113′ which is configured to be calibrated, comprising an arrangement of back-gated MOSFET, such as MP, MN in the resistive DAC of FIGS. 9, 10 or current mirror MOSFETs 1134, 1135 in the steering current DAC of FIG. 11, in particular FD-SOI MOSFET, determining the output of said internal digital to analog converter, 113′, based on the output digital signal ADCₒᵤₜ at its input, such output adjustment arrangement, e.g. the chain of decoder 1131 and DAC 1132 coupled to the circuit 232, being configured to send said calibration signal, i.e. DAC_{CAL}, which includes the correction values Steps_{Table}, to the back gates of said back-gated MOSFET, e.g., MP, MN or 1134, 1135 to modify their transconductance, e.g., g_{mDS}, i.e., their resistance or their current output.

From the description here above thus the advantages of the solution described are clear.

Advantageously, the solution described allows that during the calibration period the converter can be operated on the input signal.

Moreover, the proposed solution is adaptive to process/temperature variations.

This obtained since the architecture generates a calibration tone which generates spurs on the input of the ADC and includes a calibration unit to adjust the DAC operation in a way which minimizes such spurs.

The technique is implemented in a standard CMOS process, which is also the best process choice for low power consumption.

Without prejudice to the underlying principles, the details and embodiments may vary, even significantly, with respect to what has been described by way of example only, without departing from the extent of protection.

The extent of protection is defined by the annexed claims.

1. A conversion architecture comprising:
a Continuous Time Sigma Delta Analog to Digital Converter comprising:
a loop filter;
an analog to digital converter coupled to an output of the loop filter; and
a feedback loop configured to feed back an output of the analog to digital converter through an internal digital to analog converter to obtain an error signal with respect to an input signal, the error signal being fed to the loop filter;
a decimation chain of decimators configured to receive an output digital signal of the analog to digital converter;
a local oscillator configured to feed a clock signal to the analog to digital converter;
a frequency divider configured to receive the clock signal and provide a divided clock signal to the decimation chain of decimators; and
circuitry configured to:
obtain a calibration tone based on a divided frequency outputted by the frequency divider to the decimation chain of decimators;
inject the calibration tone in the feedback loop;
obtain an estimation of power of a spurious tone based on a decimated signal taken from the decimation chain;
generate a calibration signal as a function of the estimation of the power of the spurious tone; and
send the calibration signal to the internal digital to analog converter,
wherein the internal digital to analog converter comprises an output adjustment arrangement configured to adjust an output analog signal of the internal digital to analog converter based on the calibration signal.

2. The conversion architecture according to claim 1, wherein the circuitry comprises:
a sequencer circuit configured to:
receive the estimation of power, and
calculate correction values based on the estimation of power; and
a digital to analog converter level control circuit coupled to an output of the sequencer circuit and configured to:
receive the correction values, and
issue the calibration signal to the output adjustment arrangement based on the correction values.

3. The conversion architecture according to claim 2, wherein the sequencer circuit is configured to:
compute one or more sequences of correction values for each output level of the internal digital to analog converter;
cause the digital to analog converter level control circuit to issue the sequences of correction values as the calibration signal to the output adjustment arrangement;
store a corresponding estimation of power for each correction value in the sequences; and
identify a correction value that minimizes the estimation of power.

4. The conversion architecture according to claim 1, wherein the circuitry comprises:
a filter configured to filter the decimated signal around a selected spurious tone;
a Fast Fourier Transform circuit coupled to an output of the filter and configured to calculate a FFT power spectrum of the selected spurious tone; and
a power estimation circuit coupled to an output of the Fast Fourier Transform circuit and configured to calculate the estimation of power as a maximum amplitude of the FFT power spectrum.

5. The conversion architecture according to claim 4, wherein the circuitry comprises:
a sequencer circuit configured to:
receive the estimation of power, and
calculate correction values based on the estimation of power; and
a digital to analog converter level control circuit coupled to an output of the sequencer circuit and configured to:
receive the correction values, and
issue the calibration signal to the output adjustment arrangement based on the correction values.

6. The conversion architecture according to claim 5, wherein the sequencer circuit is configured to:
compute one or more sequences of correction values for each output level of the internal digital to analog converter;
cause the digital to analog converter level control circuit to issue the sequences of correction values as the calibration signal to the output adjustment arrangement;
store a corresponding estimation of power for each correction value in the sequences; and
identify a correction value that minimizes the estimation of power.

7. The conversion architecture according to claim 1, wherein the internal digital to analog converter comprises:
an arrangement of back-gated metal-oxide-semiconductor field-effect transistors configured to determine the output signal of the internal digital to analog converter based on the output digital signal; and
wherein the output adjustment arrangement is configured to send the calibration signal to back gates of the back-gated metal-oxide-semiconductor field-effect transistors to modify transconductance of the back-gated metal-oxide-semiconductor field-effect transistors.

8. The conversion architecture according to claim 7, wherein the back-gated metal-oxide-semiconductor field-effect transistors comprises FD-SOI MOSFETs.

9. A calibration method for a conversion architecture, the method comprising:
generating a calibration tone having an out-of-band frequency relative to a baseband signal of the conversion architecture, the conversion architecture comprising a Continuous Time Sigma Delta Analog to Digital Converter comprising a loop filter, an analog to digital converter, an internal digital to analog converter in a feedback loop, and a decimation chain of decimators;
injecting the calibration tone in an input path of the analog to digital converter;
obtaining a decimated signal from the decimation chain of decimators;
estimating power of a spurious tone in the decimated signal; and
adjusting output levels of the internal digital to analog converter with a calibration signal to reduce the estimated power.

10. The calibration method according to claim 9, wherein the adjusting the output levels comprises, for each output level of the internal digital to analog converter:
applying a sequence of increasing correction values to the output level;
measuring the estimated power of the spurious tone for each applied correction value;
storing each measured estimated power in a measurement array;
identifying a correction value in the sequence that corresponds to a minimum measured estimated power in the measurement array; and
setting the identified correction value as a calibration value in the calibration signal for the output level during operation of the conversion architecture.

11. The calibration method according to claim 10, further comprising:
selecting an order value;
performing a plurality of iterations of the adjusting the output levels;
after each iteration, updating the calibration value for each output level and decreasing the order value; and
stopping the plurality of iterations when the order value reaches a threshold value, wherein the calibration value at the stopping is used as the calibration value in the calibration signal during operation of the conversion architecture.

12. The calibration method according to claim 11, wherein a length of the sequence of increasing correction values and a voltage difference between each pair of correction values in the sequence are proportional to the order value.

13. The calibration method according to claim 11, wherein the decreasing the order value comprises dividing the order value by two.

14. A Continuous Time Sigma Delta Analog to Digital Converter comprising:
a loop filter having an input and an output;
an analog to digital converter coupled to the output of the loop filter and configured to generate an output digital signal;
a decimation chain of decimators configured to receive the output digital signal and generate a decimated signal;
a local oscillator configured to generate a clock signal for the analog to digital converter;
a frequency divider configured to divide the clock signal and provide a divided clock signal to the decimation chain of decimators;
an internal digital to analog converter configured to receive the output digital signal and generate a feedback analog signal;
a first summation circuit circuit block configured to sum the feedback analog signal and a calibration signal to generate a compensated feedback analog signal;
a second summation circuit circuit block configured to sum the compensated feedback analog signal and a calibration tone to generate a combined feedback signal, wherein the calibration tone is based on a divided frequency from the frequency divider;
a difference circuit circuit block configured to generate an error signal based on a difference between an input analog signal and the combined feedback signal, the error signal being coupled to the input of the loop filter; and
a calibration circuit configured to:
measure power of a spurious tone in the decimated signal, the spurious tone being generated by mismatch in the internal digital to analog converter in response to the calibration tone; and
generate the calibration signal to adjust the compensated feedback analog signal to reduce the power of the spurious tone.

15. The Continuous Time Sigma Delta Analog to Digital Converter according to claim 14, wherein the summation circuit circuit block is configured to inject the calibration tone at a summation node that combines the feedback analog signal with the calibration tone before the difference circuit circuit block.

16. The Continuous Time Sigma Delta Analog to Digital Converter according to claim 14, wherein the calibration tone has a frequency based on the divided clock signal from the frequency divider.

17. The Continuous Time Sigma Delta Analog to Digital Converter according to claim 16, wherein the calibration tone has a frequency equal to a sampling frequency of a last decimator in the decimation chain of decimators.

18. The Continuous Time Sigma Delta Analog to Digital Converter according to claim 14, wherein:
the spurious tone comprises a second harmonic spurious tone having a frequency that is double a frequency of the calibration tone; and
the calibration circuit is configured to measure power at the frequency of the second harmonic spurious tone.

19. The Continuous Time Sigma Delta Analog to Digital Converter according to claim 14, wherein the internal digital to analog converter comprises:
an arrangement of back-gated metal-oxide-semiconductor field-effect transistors configured to determine the output signal of the internal digital to analog converter; and
an output adjustment arrangement configured to apply the calibration signal to back gates of the back-gated metal-oxide-semiconductor field-effect transistors to modify transconductance of the back-gated metal-oxide-semiconductor field-effect transistors.

20. The Continuous Time Sigma Delta Analog to Digital Converter according to claim 19, wherein:
the internal digital to analog converter comprises a resistive digital to analog converter having a plurality of resistors;
the back-gated metal-oxide-semiconductor field-effect transistors comprise switches configured to selectively couple the plurality of resistors to reference voltages; and
the output adjustment arrangement comprises:
a first decoder configured to generate a digital maximum reference voltage control signal based on the calibration signal;
a second decoder configured to generate a digital minimum reference voltage control signal based on the calibration signal;
a maximum reference voltage digital to analog converter configured to convert the digital maximum reference voltage control signal to an analog maximum control voltage; and
a minimum reference voltage digital to analog converter configured to convert the digital minimum reference voltage control signal to an analog minimum control voltage,
wherein the analog maximum control voltage and the analog minimum control voltage are applied to back gates of the back-gated metal-oxide-semiconductor field-effect transistors.
